(19) United States
(12) Patent Application Publication
(10) Pub. No.: US 2015/0301101 A1
(43) Pub. Date: Oct. 22, 2015

(54) ADAPTIVE PMU-BASED FAULT LOCATION METHOD FOR SERIES-COMPENSATED LINES

(71) Applicant: KING FAHD UNIVERSITY OF PETROLEUM AND MINERALS, DHAHRAN (SA)

(72) Inventors: MOHAMED ALI YOUSEF ABIDO, DHAHRAN (SA); ALI HASSAN AL-MOHAMMED, DHAHRAN (SA)

(73) Assignee: KING FAHD UNIVERSITY OF PETROLEUM AND MINERALS, DHAHRAN (SA)

(21) Appl. No.: 14/259,091

(22) Filed: Apr. 22, 2014

(51) Int. Cl. G01R 31/08; G01R 25/00

(52) U.S. Cl. CPC G01R 31/088; G01R 25/00

(57) ABSTRACT

The adaptive phasor measurement unit (PMU)-based series-compensated line (SCL) fault location method uses three different sets of pre-fault voltage and current phasor measurements at both terminals of the SCL. The three sets of local PMU measurements at each terminal are used for online calculation of a respective Thevenin Equivalent (TE). This enables representation of the power system pre-fault network with a reduced two-terminal equivalent system. The PMU measurements are also utilized for online calculation of the SCL parameters. This non-iterative method does not need knowledge of a time elapsed for the wave propagation from a fault point to a sending end and a receiving end. Two subroutines S_{A} and S_{B} are used for locating faults. A selection procedure is applied for indicating the valid subroutine and, hence, the actual fault location.

### BACKGROUND OF THE INVENTION

1. Field of the Invention

The present invention relates to fault location, and particularly to an adaptive phasor measurement unit (PMU)-based fault location method for series-compensated lines (SCLs).

2. Description of the Related Art

Recent development of series compensation in power systems can greatly increase power transfer capability, improve the transient stability and damp power oscillations if carefully designed. Likewise, series compensation can minimize the amount of transmission lines needed for a certain power transfer capability of an interconnector. Installing of series compensation on existing lines is generally less expensive and less time consuming than adding new lines.

Fault location has always been an important subject to power system engineers due to the fact that accurate and swift fault location on a power network can expedite repair of faulted components, speed-up power restoration and thus enhance power system reliability and availability. Rapid restoration of service can reduce customer complaints, outage time, loss of revenue and crew repair expense. Fault location on SCLs is considered to be one of the most important tasks for the manufacturers, operators and maintenance engineers since these lines are usually spreading over a few hundreds of kilometers and are vital links between the energy production and consumption centers. However, SCLs are considered as especially difficult for fault location since series capacitors in these lines are equipped with metal-oxide varistors (MOV) for overvoltage protection. The non-linearity of MOV is well known and the accuracy in its model strongly affects the accuracy of the fault distance evaluation.

PMUs have recently evolved into mature tools and are now being utilized in the field of fault location. Recognizing the importance of the fault location function for SCLs, several PMU-based fault location algorithms have been proposed in the past literature. For example, some PMU-based fault location algorithms can be applied to any series flexible alternating current transmission system (FACTS) compensated line as they do not require the series device model. Different algorithms are proposed to locate faults on double-circuit SCLs using both synchronized and unsynchronized phasor measurements. To limit the amount of data needed to be exchanged between the line terminals, a known algorithm uses current phasors from both ends of the line and voltage phasors from one local end only. Another known fault location algorithm uses time domain measurement of the instantaneous values and it can, therefore, be applied with minimum filtering of high frequencies. Another technique uses the distributed time domain model for modeling of the transmission lines and takes advantage of only half cycle of the post-fault synchronized voltage and current samples taken from two ends of the line. In yet another technique, a two-terminal algorithm is proposed where the fault distance is determined in a general way using modal theory.

One-end fault location algorithms, applying a phase coordinates approach, have also been proposed for series-compensated transposed or untransposed parallel lines. One such algorithm applies a differential equation approach. Another algorithm applies two-end currents and one-end voltage with use of the generalized fault loop model. Some algorithms are developed using a linearized model of three-phase capacitor banks to represent the effects of compensation. In yet another scheme, a fault location algorithm is proposed using neural network and deterministic methods. Adaptive fault location aims at improving the fault location accuracy achieved by the classical non-adaptive fault location algorithms. The idea of adaptive fault location on transmission lines boils down to proper estimation of line parameters and system impedance.

Adaptive fault location aims at improving the fault location accuracy achieved by the classical non-adaptive fault location algorithms. The idea of adaptive fault location on transmission lines boils down to proper estimation of line parameters and system impedance.

Thus, an adaptive PMU-based fault location method for series-compensated lines addressing the aforementioned problems is desired.

### SUMMARY OF THE INVENTION

The adaptive phasor measurement unit (PMU)-based fault location method for series-compensated lines (SCLs) requires three different sets of pre-fault voltage and current phasor measurements at both terminals of the SCL. The three sets of local PMU measurements at each terminal are used for online calculation of the respective Thevenin Equivalent (TE). This enables representation of the power system pre-fault network with a reduced two-terminal equivalent system. The PMU measurements are also utilized for online calculation of the SCL parameters. The present method typically does not require any data to be provided by the electric utility. Such data is usually ideal and does not reflect the effect of the surrounding environment and the practical operating conditions of the power system. Moreover, the present method is non-iterative and does not need knowledge of a time elapsed for the wave propagation from a fault point to a sending end and a receiving end. The present adaptive PMU-based fault location method uses two subroutines S_{A} and S_{B} for locating faults. A selection procedure is applied for indicating the valid subroutine and, hence, the actual fault location.

These and other features of the present invention will become readily apparent upon further review of the following specification and drawings.

### BRIEF DESCRIPTION OF THE DRAWINGS

FIG. 1 is a flowchart of an embodiment of a fault location method according to the present invention.

FIG. 2 shows a sinusoidal waveform and its corresponding phasor representation.

FIG. 3 is a one line diagram of a series compensated line.

FIG. 4 is a block diagram showing a positive sequence network during normal operation.

FIG. 5 is a block diagram showing faults on a series-compensated line (SCL).

FIG. 6 is a block diagram showing a subroutine S_{A} scheme of a SCL line under a fault F_{A} according to the present invention.

FIG. 7 is a block diagram showing a subroutine S_{B} scheme of a SCL under a fault F_{B} according to the present invention.

FIG. 8 is a plot showing maximum fault location (FL) error percent versus fault type.

FIG. 9 is a plot showing an effect of fault location on FL accuracy for a fault type AG.

FIG. 10 is a plot showing an effect of fault location on FL accuracy for a fault type BC.

FIG. 11 is a plot showing an effect of fault location on FL accuracy for a fault type CAG.

FIG. 12 is a plot showing an effect of fault location on FL accuracy for a fault type ABC.

FIG. 13 is a plot showing an effect of fault resistance on FL accuracy for a fault type BG.

FIG. 14 is a plot showing an effect of fault resistance on FL accuracy for a fault type BC.

FIG. 15 is a plot showing an effect of fault resistance on FL accuracy for a fault type CAG.

FIG. 16 is a plot showing an effect of fault resistance on FL accuracy for a fault type ABC.

FIG. 17 is a plot showing an effect of fault inception angle on FL accuracy.

FIG. 18 is a plot showing an effect of pre-fault loading on FL accuracy.

FIG. 19 is a plot showing an effect of compensation degree on FL accuracy.

FIG. 20 is a plot showing an effect of source impedance and line parameter variation (%) on FL accuracy.

FIG. 21 is a generalized system for implementing embodiments of methods for adaptive PMU-based fault location for series-compensated lines (SCLs) according to the present invention.

Unless otherwise indicated, similar reference characters denote corresponding features consistently throughout the attached drawings.

### DETAILED DESCRIPTION OF THE PREFERRED EMBODIMENTS

The adaptive PMU-based fault location method for series-compensated lines (SCLs) requires three different sets of pre-fault voltage and current phasor measurements at both terminals of the SCL. The three sets of local PMU measurements at each terminal are used for online calculation of a respective Thevenin Equivalent (TE). This enables representation of the power system pre-fault network with a reduced two-terminal equivalent system. The PMU measurements are also utilized for online calculation of the SCL parameters. This non-iterative method does not need knowledge of a time elapsed for the wave propagation from a fault point to a sending end and a receiving end. Two subroutines S_{A} and S_{B} are used for locating faults. Also, a selection procedure is applied for indicating the valid subroutine and, hence, the actual fault location.

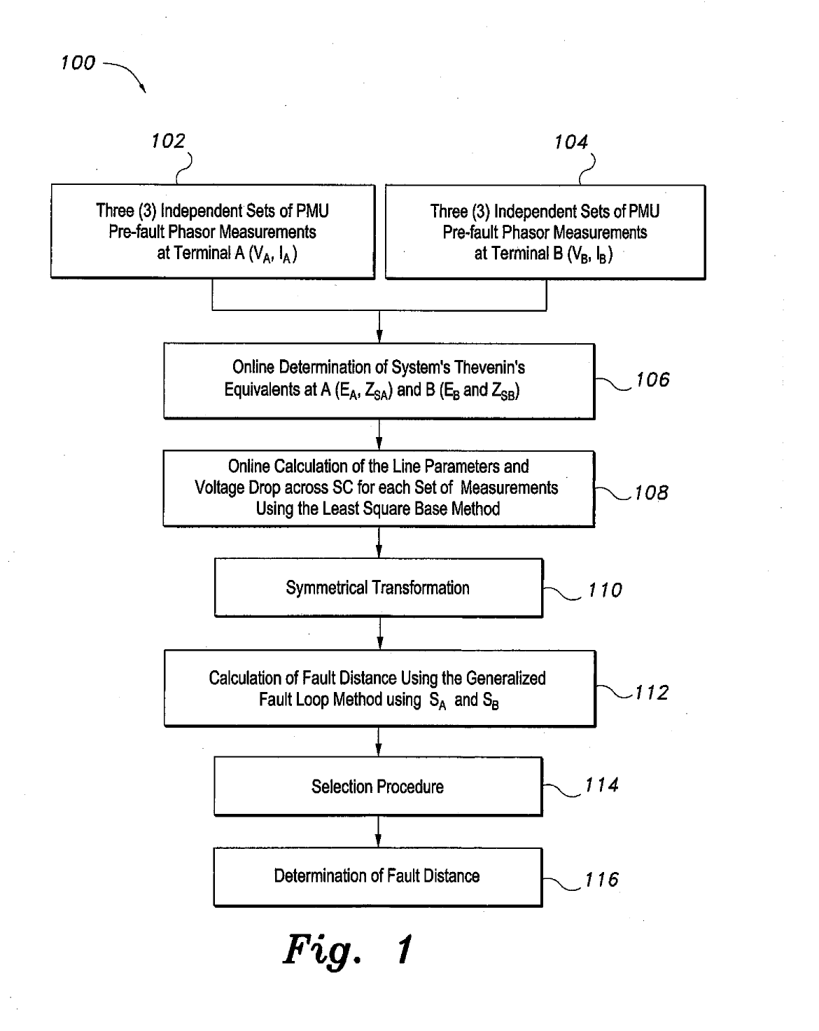

As shown in FIG. 1, the present adaptive PMU-based series-compensated line (SCL) fault location method 100 includes a first set of steps (102 and 104) that acquire three independent sets of PMU pre-fault phasor measurements at a first terminal A (V_{A}, I_{A}) and three independent sets of PMU pre-fault phasor measurements at a second terminal B (V_{B}, I_{B}), the three independent sets of PMU pre-fault phasor measurements at the first terminal A (V_{A}, I_{A}) and the three independent sets of PMU pre-fault phasor measurements at the second terminal B (V_{B}, I_{B}) having a common time reference. The common time reference can be achieved by synchronizing samples of the phasor measurements with reference to global positioning system (GPS) satellite transmissions received by at least one PMU disposed in the power system network, for example. Next, at step 106, the present method performs online calculations which determine the power distribution system's Thevenin Equivalents (TE) at A (E_{A}, Z_{SA}) and B (E_{B}, Z_{SB}). Step 108 performs an online calculation of the line parameters and the voltage drop across a series compensator or a series compensation device (SC) for each set of measurements using the least square based method. At step 110 a symmetrical transformation is performed of phasor quantities to obtain the corresponding positive, negative and zero sequence quantities.

At step 112 the present method calculates fault distance using a generalized fault loop method based on fault location subroutines S_{A} and S_{B} by determining fault distances of a first fault distance based on the symmetrical transformation using a fault loop on a first subroutine network (S_{A}) including a line that includes the first terminal and the SC and of a second fault distance based on the symmetrical transformation using a fault loop on a second subroutine network (S_{B}) including a line between the second terminal and the SC, for each subroutine network the total line length being the distance between the first terminal and the second terminal. The selection procedure at step 114 selects the appropriate subroutine S_{A} or S_{B} as the valid subroutine network to perform the actual fault location fault distance determination. At step 116, the selected subroutine performs the fault distance determination by determining an actual fault location fault distance by a fault loop on the selected one of the first subroutine network (S_{A}) or the second subroutine network (S_{B}) as the valid subroutine network. Implementation of the steps of method 100 can be achieved using a controller/processor.

In this regard, FIG. 21 illustrates a generalized system 2100 for implementing embodiments of methods for adaptive PMU-based fault location for series-compensated lines (SCLs), although it should be understood that the generalized system 2100 can represent, for example, a stand-alone computer, computer terminal, portable computing device, networked computer or computer terminal, or networked portable device. Data can be entered into the system 2100 by the user or can be received by the system 2100 via any suitable type of user or other suitable interface 2108, and can be stored in a computer readable memory 2104, which can be any suitable type of computer readable and programmable memory. Calculations implementing the adaptive fault location determination for adaptive PMU-based fault location for SCLs are performed by a controller/processor 2102, which can be any suitable type of computer processor, and can be displayed to the user on a display 2106, which can be any suitable type of computer display, for example.

The controller/processor 2102 can be associated with, or incorporated into, any suitable type of computing device, for example, a personal computer or a programmable logic controller. The display 2106, the controller/processor 2102, the memory 2104, and any associated computer readable media are in communication with one another by any suitable type of data bus, as is well known in the art.

Examples of computer readable media include a magnetic recording apparatus, non-transitory computer readable storage memory, an optical disk, a magneto-optical disk, and/or a semiconductor memory (for example, RAM, ROM, etc.). Examples of magnetic recording apparatus that may be used in addition to memory 2104, or in place of memory 2104, include a hard disk device (HDD), a flexible disk (FD), and a magnetic tape (MT). Examples of the optical disk include a DVD (Digital Versatile Disc), a DVD-RAM, a CD-ROM (Compact Disc-Read Only Memory), and a CD-R (Recordable)/RW.

Notation used in the Figures, including FIG. 1, is set forth in Table 1.

TABLE 1
NOTATION USED

| Parameter | Definition |
|---|---|
| E_{A}, Z_{SA} | The TE of the system at terminal A |
| E_{B}, Z_{SB} | The TE of the system at terminal B |
| i | Integer to represent the measurement set number |
| Vₐᵢ, Iₐᵢ | The i^{th} phasor measurement of positive sequence |
| | voltage and current at terminal A |
| V_{bi}, I_{bi} | The i^{th} phasor measurement of positive sequence |
| | voltage and current at terminal B |
| Vᵣᵢ | The voltage at the left side of location R |
| Vₛᵢ | The voltage drop across SC at location R |
| Iᵣᵢ | The current flowing through SC at location R |
| Z, Y | The line impedance, shunt admittance |
| l, l₁, l₂ | Total length of the line, length of segment AR, |
| | length of segment BR |

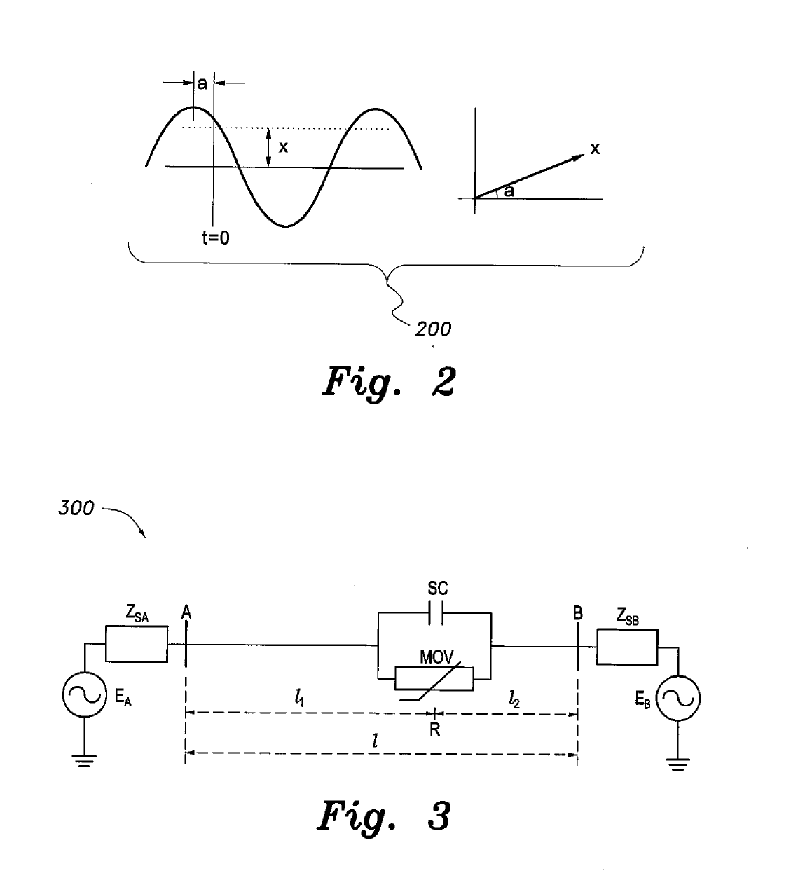

Referring to plots 200 of FIG. 2, let us consider the steady-state waveform of a nominal power frequency signal. If the waveform observation starts at the instant t=0, the steady-state waveform can be represented by a complex number with a magnitude equal to the root mean square (rpm) value of the signal and with a phase angle equal to the angle a. In a digital measuring system, samples of the waveform for one (nominal) period are collected, starting at t=0, and then the fundamental frequency component of the Discrete Fourier Transform (DFT) is calculated according to the relation:

$$X = \frac{\sqrt{2}}{N} {\sum }_{k = 1}^{N} {x}_{k} {e}^{- j 2 π k / N} \qquad ( 1 )$$

where N is the total number of samples in one period, X is the phasor, and xₖ is the waveform samples. The Discrete Fourier Transform (DFT) can be used to extract the voltage and current (V_{A}, I_{A}) phasors and the voltage and current (V_{B}, I_{B}) phasors. Advantages of this definition of the phasor include the fact that it uses a number of samples N of the waveform, and consequently can be an accurate representation of the fundamental frequency component when other transient components are present. Line parameters determined can include the determination of series resistance, series reactance and shunt admittance of the SCL, for example. In performing a symmetrical transformation of the phasor quantities to obtain the corresponding positive, negative and zero sequence quantities, once the phasors (Xₐ, X_{b} and X_{c}) for the three phases are computed, positive, negative and zero sequence phasors (X₁, X₂ and X₀) can be obtained using the following transformation calculating a solution to the equation characterized by the relation:

$$[ \begin{matrix}{X}_{1} \\ {X}_{2} \\ {X}_{0}\end{matrix} ] = \frac{1}{3} [ \begin{matrix}1 & {e}^{j2 π / 3} & {e}^{j 4 π / 3} \\ 1 & {e}^{j 4 π / 3} & {e}^{j 2 π / 3} \\ 1 & 1 & 1\end{matrix} ] \cdot [ \begin{matrix}{X}_{a} \\ {X}_{b} \\ {X}_{c}\end{matrix} ] . \qquad ( 2 )$$

When several voltages and currents in a power system are measured and converted to phasors in this fashion, they are on a common reference if they are sampled at precisely the same instant. This can be achieved in a substation, where the common sampling clock pulses can be distributed to all the measuring systems. However, to measure common-reference phasors in substations separated from each other by long distances, the task of synchronizing the sampling clocks is not a trivial one. Only with the advent of the Global Positioning System (GPS) satellite transmissions, the PMU technology has now reached a stage whereby synchronization of the sampling processes in distant substations can be achieved economically and with an error of less than 1 microsecond (μs). This error corresponds to approximately 0.021° for a 60 hertz (Hz) system and 0.018° for a 50 Hz system, and is relatively more accurate than any present application likely can demand.

Adaptive fault location in embodiments of methods for adaptive fault location in power system networks use local PMU measurements to determine online systems Thevenin Equivalents (TEs) at the terminals of the line. This is possible with PMUs because voltage and current phasors are provided at high rates of one measurement per cycle, which typically is not possible with the conventional supervisory control and data acquisition (SCADA) systems because these SCADA systems are relatively slow and generally cannot handle the relatively high rates. Three consecutive voltage and current (V, I) measurements can be used to determine an exact TE at the two line terminals. It is essential to have the three sets of phasor measurements refer to the same reference. From the first and second sets of voltage and current measurements, the following equation can be written:

$${( r + \frac{{P}_{1} - {P}_{2}}{{I}_{1}^{2} - {I}_{2}^{2}} )}^{2} + {( x - \frac{{Q}_{1} - {Q}_{2}}{{I}_{1}^{2} - {I}_{2}^{2}} )}^{2} = \frac{{V}_{2}^{2} - {V}_{1}^{2}}{{I}_{1}^{2} - {I}_{2}^{2}} + {( \frac{{P}_{1} - {P}_{2}}{{I}_{1}^{2} - {I}_{2}^{2}} )}^{2} + {( \frac{{Q}_{1} - {Q}_{2}}{{I}_{1}^{2} - {I}_{2}^{2}} )}^{2} \qquad ( 3 )$$

where r and x are the resistance and the reactance, respectively, of the Thevenin impedance (Zₜₕ). P and Q are the real and reactive powers, respectively. Equation (3) represents a circle in the impedance plane defining the locus for the Zₜₕ that satisfies the two measurements but it does not define a specific value for the Zₜₕ. Therefore, a third measurement is required which can be used with either the first or the second measurement in the same way to produce another circle. The intersection of the two circles is the equivalent Zₜₕ. The coordinates of the intersection point in the Z-plane define the values of the resistance and reactance of the Zₜₕ. The equivalent Thevenin voltage (Eₜₕ) at a node is found knowing the Zₜₕ and the local V and I measurements at that node as described by:

V=Eₜₕ+Zₜₕ·I. (4)

The other important aspect of adaptive fault location is concerned with online determination of series resistance, series reactance and shunt admittance of the SCL under study. The one line diagram of a series compensated network and the corresponding positive sequence network during normal operation are shown in the SCL 300 of FIG. 3 and in the positive sequence network 400 of FIG. 4, respectively. An SCL is usually classified as a long line and it is therefore represented using the distributed parameter model. The series compensator (SC) or series compensation device is located at location R and it can be a simple capacitor bank or a more complicated thyristor-controlled power flow controller.

Assuming three sets of measurements (1=1, 2, 3), obtained according to different operation conditions, the unknown variables can be defined as:

X=[x₁,x₂ . . . ,x₉]^{T} (5)

where x₁, . . . , x₆ are variables used to represent voltage across the compensation device for each set, i.e., Vₛ₁=x₁e^{jx}^{₂}, Vₛ₂=x₃e^{jx}^{₄}, Vₛ₃=x₅e^{jx}^{₆}, and x₇, x₈, x₉ are positive sequence transmission line series resistance, series reactance and shunt susceptance per unit length, respectively. By employing the defined variables, the following equations for each set of measurements based on the network 400 shown in FIG. 4 can be obtained as:

x₂ᵢ₋₁e^{jx}^{₂ᵢ} cos h(γl₁)+V_{qi} cos h(γl)+I_{qi}Z_{c} sin h(γl)−Vₚᵢ=0, and (6)

$${x}_{2 i - 1} {e}^{j {x}_{2 i}} \frac{sinh ( γ {l}_{1} )}{{Z}_{c}} + {I}_{qi} cosh ( γ l ) + \frac{{V}_{qi}}{{Z}_{c}} sinh ( γ l ) - {I}_{pi} = 0 \qquad ( 7 )$$

where,

Z_{c}=\sqrt{(x₇+jx₈)/(jx₉)} (8)

and

γ=\sqrt{(x₇+jx₈)(jx₉)}. (9)

Each of the above complex equations can be arranged into two real equations for every set of measurements. With 9 unknowns and a total of 12 real equations formed for the three sets of measurements, the classical least squares based method can be applied to obtain a relatively more robust estimate of the unknowns, for example.

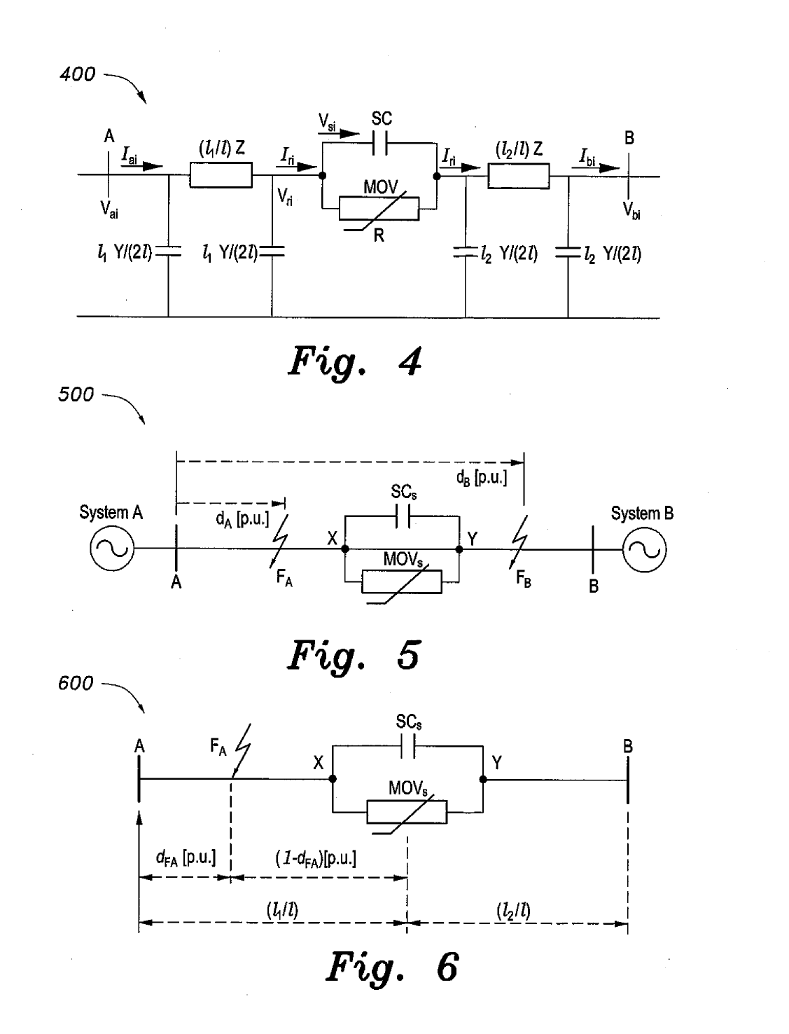

A fault is of a random nature and therefore faults appearing at both sides of the three-phase capacitor compensating bank (faults F_{A} and F_{B} in network 500 shown in FIG. 5) shall be considered. As a result, two subroutine networks S_{A} (Block 600 shown in FIG. 6) and S_{B} (Block 700 shown in FIG. 7) are utilized for locating these hypothetical faults. Also, the selection procedure is applied for indicating the valid subroutine network and, hence, the actual fault location.

The sought fault distance is determined using a fault loop method as includes the following relations assuming that the fault location function is available at both terminal A and terminal B. In this regard, determining fault distances of the first fault distance d_{FA} for the first subroutine network (S_{A}) and of the second fault distance d_{FB} for the second subroutine network (S_{B}), are respectively characterized by the following relations for determining d_{FA} and d_{FB}:

$$\begin{matrix}{d}_{FA} = \frac{real ( {V}_{Ap} ) imag ( {I}_{FA} ) - imag ( {V}_{Ap} ) real ( {I}_{FA} )}{real ( {Z}_{1 LA} {I}_{Ap} ) imag ( {I}_{FA} ) - imag ( {Z}_{1 LA} {I}_{Ap} ) real ( {I}_{FA} )} \\ and & ( 10 ) \\ {d}_{FB} = \frac{real ( {V}_{Bp} ) imag ( {I}_{FB} ) - imag ( {V}_{Bp} ) real ( {I}_{FB} )}{real ( {Z}_{1 LB} {I}_{Bp} ) imag ( {I}_{FB} ) - imag ( {Z}_{1 LB} {I}_{Bp} ) real ( {I}_{FB} )} & ( 11 )\end{matrix}$$

where V_{Ap}, V_{Bp} is the fault loop voltage for a fault on section A-X, section B-Y, I_{Ap}, I_{Bp} is the fault loop current for a fault on section A-X, section B-Y, I_{FA}, I_{FB} is the total fault current for a fault on section A-X, section B-Y, and Z_{1LA}, Z_{1LB} is the positive sequence impedance of the line section A-X, the line section B-Y.

The relative fault distances d_{FA}, d_{FB} can be recalculated into the distances d_{A}, d_{B}, as an actual fault location fault distance, by a fault loop on the selected one of the first subroutine network (S_{A}) or the second subroutine network (S_{B}) as the valid subroutine network, which are expressed in [p.u.] but related to the whole or total line length as follows:

d_{A}=d_{FA}·(l₁/l) (12)

and

d_{B}=(l₁/l)+(1−d_{FB})·(l₂/l), (13)

where d_{A} is the actual fault location fault distance where the first subroutine network (S_{A}) is the valid subroutine network, d_{FA} is the relative distance between the fault and the first terminal of the first subroutine network (S_{A}), d_{B} is the actual fault location fault distance where the second subroutine network (S_{B}) is the valid subroutine network, d_{FB} is the relative distance between the fault and the second terminal of the second subroutine network (S_{B}), l is the total line length, l₁ is a length of a line segment between the first terminal and the SC and l₂ is a length of a line segment between the second terminal and the SC.

With respect to data generation and conditioning, a 400 kV transmission network is considered, for example, with a series compensated line, such as depicted in the series compensated line 300 shown in FIG. 3. Faults at both sides of the series compensating unit in sections A-X and B-Y are studied. The line, compensated at a 70% degree of compensation, is modeled in PSCAD/EMTDC with its distributed parameters. The relationship between voltage (Vᵥ) and current (iᵥ) of the MOV is approximated by the following non-linear equation:

$${i}_{v} = {{I}_{c} ( \frac{{V}_{v}}{{V}_{p}} )}^{α} , \qquad ( 14 )$$

where I_{c} is the MOV coordination current, Vₚ is the MOV protective level voltage defined at I_{c}, and α is a manufacturing parameter of the MOV material.

Table 2 shows the simulation parameters. The current transformers (CTs) and the voltage transformers (VTs) located at each line terminal are assumed as ideal devices, for example. The three-phase voltage and current signals are sampled at a frequency of 240 Hz which corresponds to 4 samples per cycle and are stored for post-processing. The DFT given by (1) is applied to extract the voltage and current phasors. The present adaptive PMU-based fault location algorithm for SCLs can be implemented in MATLAB, for example.

TABLE 2
Parameters of the 400 KV Series Compensated Network

| Parameter | Value | |
|---|---|---|
| l | 300 | km |
| l₁ | 150 | km |
| Z_{1L} | 8.28 + j94.5 | Ω |
| Z_{0L} | 82.5 + j307.9 | Ω |
| C_{1L} | 13 | nF/km |
| C_{0L} | 8.5 | nF/km |
| I_{c} | 1 | kA |
| Vₚ | 150 | kV |

| | |
|---|---|
| α | 23 |

The percentage error used to measure the accuracy of the present adaptive PMU-based fault location algorithm for SCLs can be expressed as:

$$\% Error = \frac{\vert Actual location - Estimated location \vert}{Total line length} \times 100. \qquad ( 15 )$$

TABLE 3
Fault-Location Estimates For Single-Line-to-Ground Faults

| Fault | Fault | Actual | Estimated | Error of Estimated |
|---|---|---|---|---|
| Type | Res. (Ω) | FL (p.u) | FL (p.u) | FL (%) |
| AG | 10 | 0.2 | 0.1992 | 0.3781 |
| | | 0.4 | 0.4009 | 0.2282 |
| | | 0.6 | 0.6047 | 0.7757 |
| | | 0.8 | 0.8005 | 0.0601 |
| | 100 | 0.2 | 0.1990 | 0.5202 |
| | | 0.4 | 0.4050 | 1.2450 |
| | | 0.6 | 0.6075 | 1.2459 |
| | | 0.8 | 0.7943 | 0.7180 |
| BG | 10 | 0.2 | 0.2032 | 1.5769 |
| | | 0.4 | 0.4094 | 2.3518 |
| | | 0.6 | 0.5948 | 0.8610 |
| | | 0.8 | 0.7960 | 0.4940 |
| | 100 | 0.2 | 0.2035 | 1.7500 |
| | | 0.4 | 0.4083 | 2.0750 |
| | | 0.6 | 0.5932 | 1.1333 |
| | | 0.8 | 0.7953 | 0.5875 |
| CG | 10 | 0.2 | 0.2013 | 0.6626 |
| | | 0.4 | 0.4068 | 1.7103 |
| | | 0.6 | 0.5927 | 1.2193 |
| | | 0.8 | 0.7997 | 0.0401 |
| | 100 | 0.2 | 0.1989 | 0.5478 |
| | | 0.4 | 0.4001 | 0.0129 |
| | | 0.6 | 0.5972 | 0.4600 |
| | | 0.8 | 0.8026 | 0.3271 |

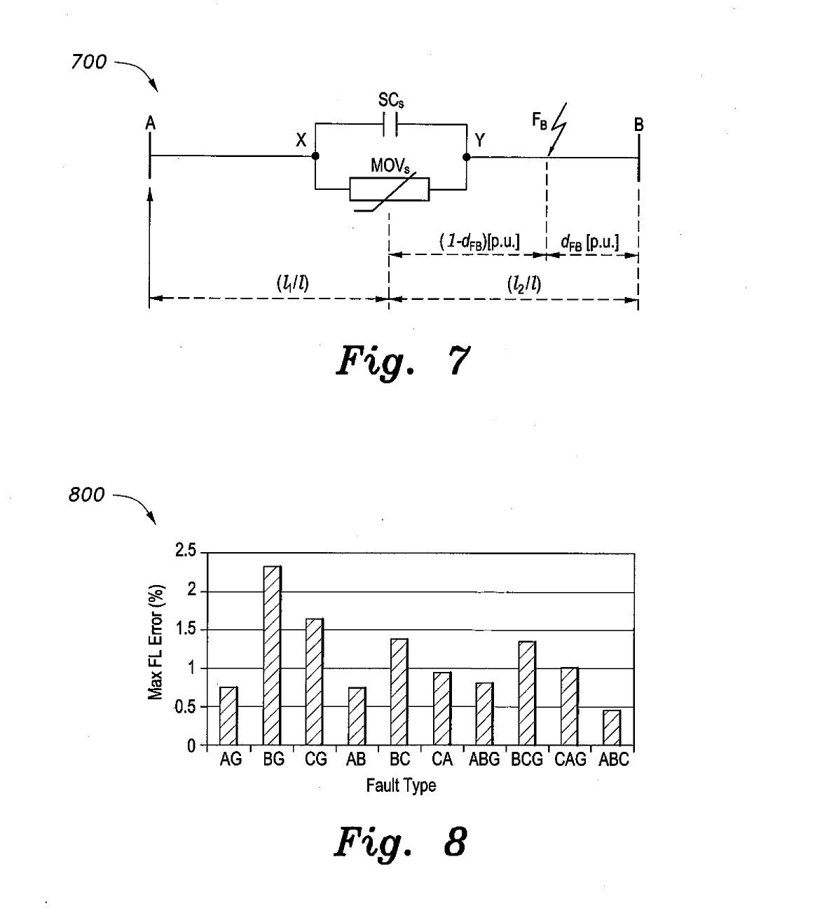

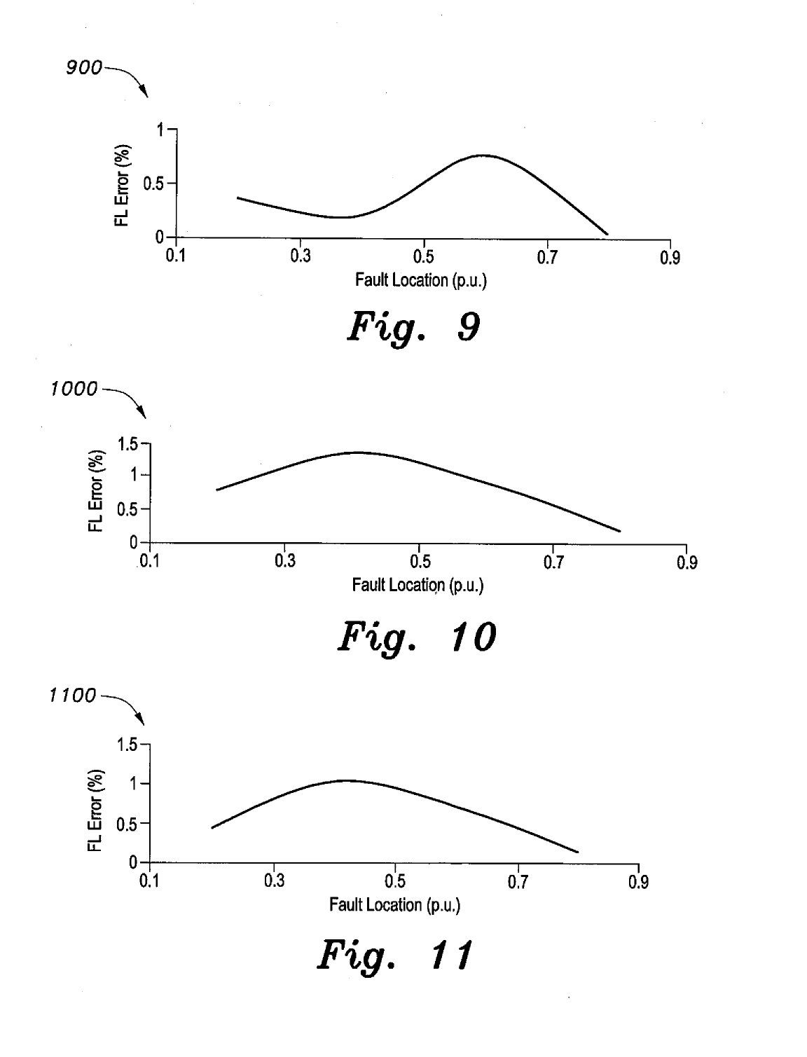

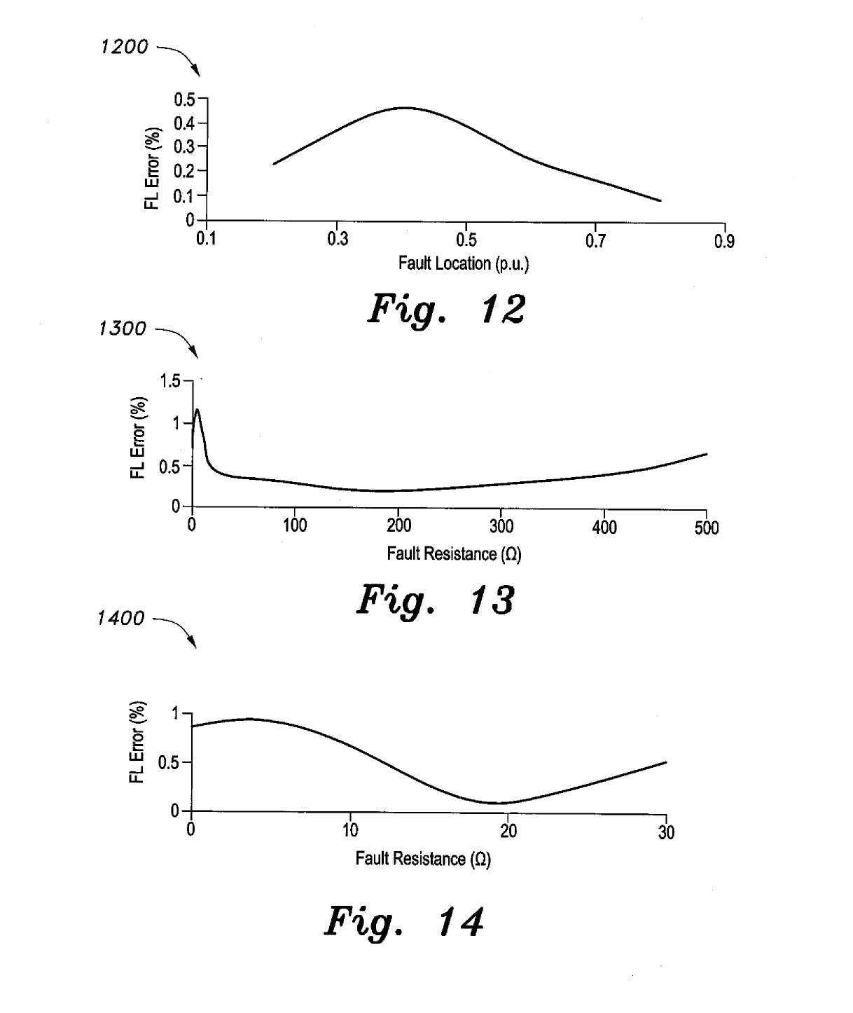

To test the accuracy of the present adaptive PMU-based fault location algorithm for SCLs in embodiments of an adaptive PMU-based fault location method for SCLs, different type of faults with different fault locations have been simulated. Tables 3 through 6 present the fault location estimates obtained for different types of faults. The fault type, fault resistance and actual fault location are given in the first column, the second column and the third column of the corresponding table, respectively. The estimated distance to a fault and the estimation errors resulting from the present fault location method are respectively displayed in the fourth column and the fifth column of the corresponding table. From the results obtained and as depicted in the plots 800 through 1200 of FIGS. 8 through 12 respectively, it is observed that embodiments of the present adaptive PMU-based fault location method for SCLs can be relatively very accurate and relatively independent of the fault type and fault location.

TABLE 4
Fault-Location Estimates For Line-To-Line Faults

| Fault | Fault | Actual | Estimated | Error of Estimated |
|---|---|---|---|---|
| Type | Res. (Ω) | FL (p.u) | FL (p.u) | FL (%) |
| AB | 1 | 0.2 | 0.2005 | 0.2298 |
| | | 0.4 | 0.4032 | 0.7964 |
| | | 0.6 | 0.5968 | 0.5364 |
| | | 0.8 | 0.7995 | 0.0603 |
| | 10 | 0.2 | 0.2007 | 0.3689 |
| | | 0.4 | 0.4043 | 1.0704 |
| | | 0.6 | 0.5960 | 0.6590 |
| | | 0.8 | 0.7995 | 0.0602 |
| BC | 1 | 0.2 | 0.2016 | 0.7921 |
| | | 0.4 | 0.4054 | 1.3575 |
| | | 0.6 | 0.5945 | 0.9191 |
| | | 0.8 | 0.7984 | 0.1962 |
| | 10 | 0.2 | 0.2021 | 1.0405 |
| | | 0.4 | 0.4053 | 1.3206 |
| | | 0.6 | 0.5960 | 0.6743 |
| | | 0.8 | 0.7989 | 0.1364 |
| CA | 1 | 0.2 | 0.2007 | 0.3467 |
| | | 0.4 | 0.4038 | 0.9473 |
| | | 0.6 | 0.5955 | 0.7501 |
| | | 0.8 | 0.7991 | 0.1148 |
| | 10 | 0.2 | 0.2007 | 0.3596 |
| | | 0.4 | 0.4061 | 1.5241 |
| | | 0.6 | 0.5940 | 1.0040 |
| | | 0.8 | 0.7978 | 0.2713 |

TABLE 5
Fault-Location Estimates For Line-to-Line-to-Ground Faults

| Fault | Fault | Actual | Estimated | Error of Estimated |
|---|---|---|---|---|
| Type | Res. (Ω) | FL (p.u) | FL (p.u) | FL (%) |
| ABG | 5 | 0.2 | 0.2005 | 0.2640 |
| | | 0.4 | 0.4033 | 0.8264 |
| | | 0.6 | 0.5968 | 0.5359 |
| | | 0.8 | 0.7995 | 0.0567 |
| | 50 | 0.2 | 0.2005 | 0.2498 |
| | | 0.4 | 0.4033 | 0.8239 |
| | | 0.6 | 0.5969 | 0.5097 |
| | | 0.8 | 0.7996 | 0.0515 |
| BCG | 5 | 0.2 | 0.2014 | 0.6984 |
| | | 0.4 | 0.4054 | 1.3455 |
| | | 0.6 | 0.5946 | 0.8983 |
| | | 0.8 | 0.7986 | 0.1744 |
| | 50 | 0.2 | 0.2014 | 0.6810 |
| | | 0.4 | 0.4054 | 1.3465 |
| | | 0.6 | 0.5947 | 0.8862 |
| | | 0.8 | 0.7985 | 0.1841 |
| CAG | 5 | 0.2 | 0.2009 | 0.4570 |
| | | 0.4 | 0.4042 | 1.0420 |
| | | 0.6 | 0.5957 | 0.7178 |
| | | 0.8 | 0.7988 | 0.1442 |
| | 50 | 0.2 | 0.2008 | 0.3992 |
| | | 0.4 | 0.4038 | 0.9387 |
| | | 0.6 | 0.5957 | 0.7108 |
| | | 0.8 | 0.7991 | 0.1143 |

TABLE 6
Fault-Location Estimates For Three-Phase Faults

| Fault | Fault | Actual | Estimated | Error of Estimated |
|---|---|---|---|---|
| Type | Res. (Ω) | FL (p.u) | FL (p.u) | FL (%) |
| ABC | 1 | 0.2 | 0.1995 | 0.2277 |
| | | 0.4 | 0.4019 | 0.4638 |
| | | 0.6 | 0.5985 | 0.2572 |
| | | 0.8 | 0.8007 | 0.0871 |
| | 10 | 0.2 | 0.1957 | 2.1477 |
| | | 0.4 | 0.3968 | 0.8035 |
| | | 0.6 | 0.6063 | 1.0547 |
| | | 0.8 | 0.8052 | 0.6521 |

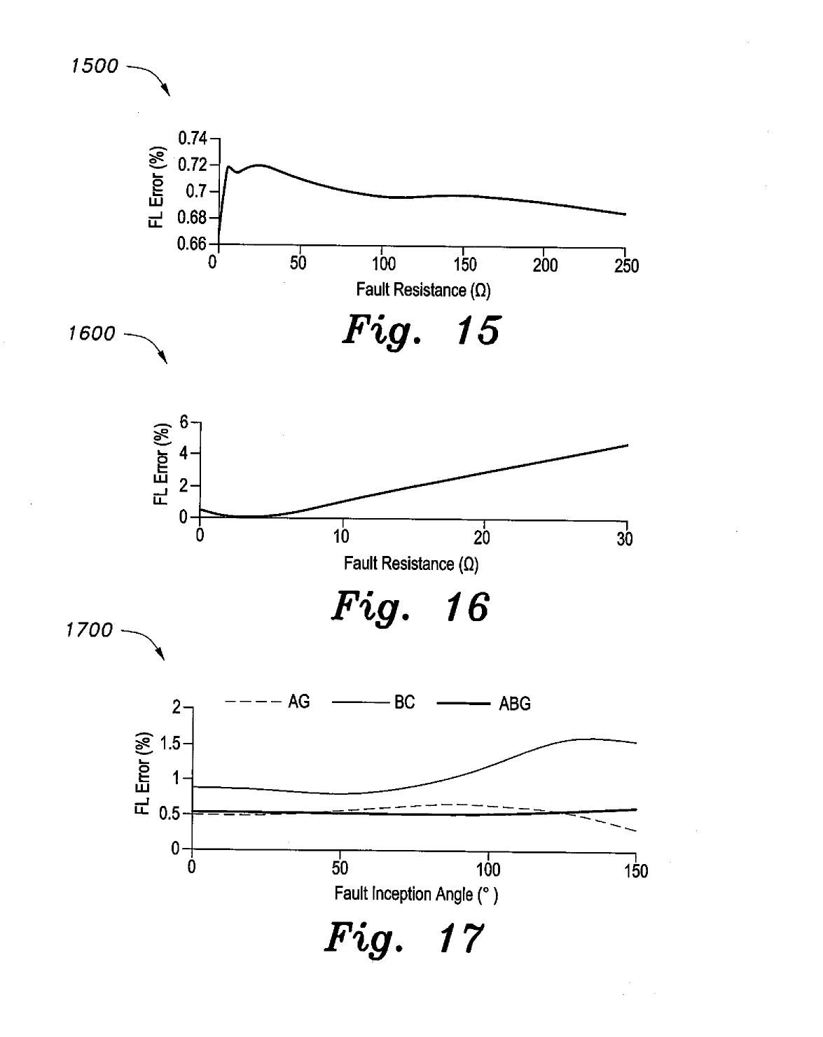

The effect of the variation of the fault resistance in the present adaptive PMU-based fault location method algorithm's accuracy for various types of faults are shown respectively in Tables 7 through 10 assuming that the fault occurs at a distance of 0.6 p.u. from terminal A. Faults involving ground have been investigated for fault resistance values varying from 0Ω to 500Ω. This fault resistance range can capture low-resistance and high-resistance faults, for example. Faults not involving a ground have been investigated for resistance values ranging between 0Ω to 30Ω, for example. Referring to the aforementioned tables and as depicted in the plots 1300 through 1600 of FIGS. 13 through 16, respectively, it can be easily seen that the fault location estimates can be relatively very accurate and virtually independent of the fault resistance in embodiments of an adaptive PMU-based fault location method for SCLs.

TABLE 7
Influence of the Fault Resistance on the Present Algorithm's
Accuracy for Single-Line-to-Ground Faults

| | Fault Type | | | | | |
|---|---|---|---|---|---|---|
| | AG | | | | | |
| | Estimated | | BG | | CG | |
| | (Estim.) | Error of | Estim. | Error of | Estim. | Error of |
| Fault Res. | FL | Estim. | FL | Estim. | FL | Estim. |
| (Ω) | (p. u) | FL (%) | (p. u) | FL (%) | (p. u) | FL (%) |
| 0 | 0.5969 | 0.5087 | 0.5955 | 0.7470 | 0.5948 | 0.8673 |
| 1 | 0.5972 | 0.4740 | 0.5946 | 0.9034 | 0.5945 | 0.9193 |
| 5 | 0.5999 | 0.0128 | 0.5929 | 1.1866 | 0.5943 | 0.9518 |
| 10 | 0.6047 | 0.7757 | 0.5948 | 0.8610 | 0.5927 | 1.2193 |
| 20 | 0.6055 | 0.9157 | 0.6028 | 0.4595 | 0.5822 | 2.9706 |
| 50 | 0.5864 | 2.2594 | 0.6022 | 0.3667 | 0.6075 | 1.250 |
| 100 | 0.6075 | 1.2459 | 0.6018 | 0.3001 | 0.5972 | 0.4600 |
| 200 | 0.6049 | 0.8180 | 0.6013 | 0.2167 | 0.5849 | 2.5167 |
| 400 | 0.5863 | 2.2827 | 0.5975 | 0.4167 | 0.5859 | 2.350 |
| 500 | 0.5792 | 3.4676 | 0.5960 | 0.6667 | 0.5381 | 1.9833 |

TABLE 8
Influence of the Fault Resistance on the Present Algorithm's
Accuracy for Line-to-Line Faults

| | Fault Type | | | | | |
|---|---|---|---|---|---|---|
| | AB | | | | | |
| | Estimated | | BC | | CA | |
| | (Estim.) | Error of | Estim. | Error of | Estim. | Error of |
| Fault Res. | FL | Estim. | FL | Estim. | FL | Estim. |
| (Ω) | (p. u) | FL (%) | (p. u) | FL (%) | (p. u) | FL (%) |
| 0 | 0.5969 | 0.5193 | 0.5947 | 0.8832 | 0.5959 | 0.6846 |
| 0.5 | 0.5969 | 0.5244 | 0.5946 | 0.9058 | 0.5957 | 0.7226 |
| 1 | 0.5968 | 0.5364 | 0.5945 | 0.9191 | 0.5955 | 0.7501 |
| 2.5 | 0.5966 | 0.5607 | 0.5943 | 0.9483 | 0.5950 | 0.8360 |
| 5 | 0.5964 | 0.5943 | 0.5945 | 0.9248 | 0.5943 | 0.9435 |
| 7.5 | 0.5963 | 0.6244 | 0.5950 | 0.8290 | 0.5940 | 0.9993 |
| 10 | 0.5960 | 0.6590 | 0.5960 | 0.6743 | 0.5940 | 1.0040 |
| 15 | 0.5953 | 0.7757 | 0.5983 | 0.2760 | 0.5947 | 0.8834 |
| 20 | 0.5939 | 1.0113 | 0.6007 | 0.1126 | 0.5964 | 0.5996 |
| 30 | 0.5893 | 1.7786 | 0.6033 | 0.5459 | 0.6022 | 0.3613 |

TABLE 9
Influence of the Fault Resistance on the Present Algorithm's
Accuracy for Line-to-Line-to-Ground Faults

| | Fault Type | | | | | |
|---|---|---|---|---|---|---|
| | ABG | | | | | |
| | Estimated | | BCG | | CAG | |
| | (Estim.) | Error of | Estim. | Error of | Estim. | Error of |
| Fault Res. | FL | Estim. | FL | Estim. | FL | Estim. |
| (Ω) | (p. u) | FL (%) | (p. u) | FL (%) | (p. u) | FL (%) |
| 0 | 0.5967 | 0.5423 | 0.5946 | 0.8966 | 0.5960 | 0.6660 |
| 1 | 0.5968 | 0.5414 | 0.5946 | 0.8972 | 0.5959 | 0.6797 |
| 5 | 0.5968 | 0.5359 | 0.5946 | 0.8983 | 0.5957 | 0.7178 |
| 10 | 0.5969 | 0.5239 | 0.5946 | 0.9017 | 0.5957 | 0.7148 |
| 25 | 0.5969 | 0.5116 | 0.5946 | 0.8986 | 0.5957 | 0.7202 |
| 50 | 0.5969 | 0.5097 | 0.5947 | 0.8862 | 0.5957 | 0.7108 |
| 100 | 0.5969 | 0.5167 | 0.5946 | 0.8927 | 0.5958 | 0.6974 |
| 150 | 0.5969 | 0.5129 | 0.5947 | 0.8905 | 0.5958 | 0.6993 |
| 200 | 0.5969 | 0.5097 | 0.5947 | 0.8757 | 0.5958 | 0.6931 |
| 250 | 0.5970 | 0.5076 | 0.5947 | 0.8794 | 0.5959 | 0.6857 |

TABLE 10
Influence of the Fault Resistance on the Present
Algorithm's Accuracy for Three-Phase Faults

| Fault | Estimated | Error of Estimated |
|---|---|---|
| Res. (Ω) | FL (p.u) | FL (%) |
| 0 | 0.5969 | 0.5171 |
| 0.5 | 0.5973 | 0.4507 |
| 1 | 0.5985 | 0.2572 |
| 2.5 | 0.5989 | 0.1871 |
| 5 | 0.6011 | 0.1825 |
| 7.5 | 0.6036 | 0.5998 |
| 10 | 0.6063 | 1.0547 |
| 15 | 0.6121 | 2.0149 |
| 20 | 0.6179 | 2.9878 |
| 30 | 0.6286 | 4.7724 |

The effect of the variation of the fault inception angle on the present adaptive PMU-based fault location method algorithm's accuracy for AG, BC and ABG faults is shown in Table 11 assuming that the fault occurs at a distance of 0.6 p.u. from terminal A. The fault inception angle is varied from 0° to 150°, for example. It can be observed that the present algorithm can be relatively highly accurate and virtually independent of the fault inception angle with an average error of 0.523%, 1.139% and 0.552% for AG, BC and ABG faults, respectively. Plot 1700 of FIG. 17 depicts, for example, the effect of the fault inception angle on the present adaptive PMU-based fault location algorithm's accuracy in embodiments of an adaptive PMU-based fault location method for SCLs.

TABLE 11
Influence of the Fault Inception Angle on the Present
Algorithm's Accuracy

| | Fault Type | | | | | |
|---|---|---|---|---|---|---|
| | AG | | | | | |
| | Estimated | | BC | | ABG | |
| Fault | (Estim.) | Error of | Estim. | Error of | Estim. | Error of |
| Inception | FL | Estim. | FL | Estim. | FL | Estim. |
| Angle (°) | (p. u) | FL (%) | (p. u) | FL (%) | (p. u) | FL (%) |
| 0 | 0.5969 | 0.5087 | 0.5947 | 0.8832 | 0.5967 | 0.5423 |
| 30 | 0.5969 | 0.5184 | 0.5950 | 0.8376 | 0.5968 | 0.5375 |
| 45 | 0.5967 | 0.5450 | 0.5951 | 0.8135 | 0.5968 | 0.5303 |
| 60 | 0.5965 | 0.5892 | 0.5951 | 0.8209 | 0.5969 | 0.5204 |
| 90 | 0.5960 | 0.6632 | 0.5936 | 1.0698 | 0.5969 | 0.5165 |
| 120 | 0.5965 | 0.5821 | 0.5910 | 1.5064 | 0.5967 | 0.5577 |
| 135 | 0.5972 | 0.4640 | 0.5903 | 1.6202 | 0.5965 | 0.5907 |
| 150 | 0.5981 | 0.3136 | 0.5906 | 1.5641 | 0.5963 | 0.6186 |

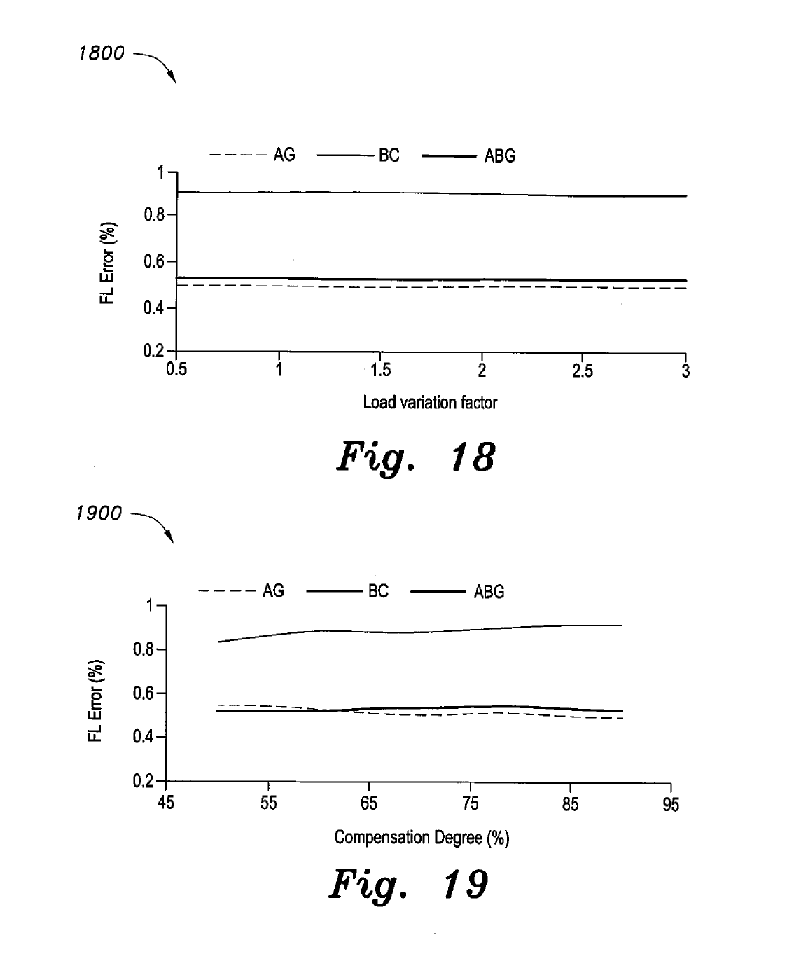

Table 12 shows the influence of the pre-fault loading on the present adaptive PMU-based fault location method algorithm's accuracy for AG, BC and ABG faults assuming that these faults occur at a 0.6 p.u. distance from terminal A. The pre-fault loading is varied from 0.5 to 3 times its base case value, for example. It can be observed that the present algorithm is relatively highly accurate and relatively independent of the pre-fault loading with an average error of 0.496%, 0.909% and 0.529% for AG, BC and ABG faults, respectively. Plot 1800 of FIG. 18 depicts, for example, the effect of the pre-fault loading on the present adaptive PMU-based fault location algorithm's accuracy in embodiments of an adaptive PMU-based fault location method for SCLs.

TABLE 12
Influence of the Pre-Fault Loading at Terminal-A
on the Present Algorithm's Accuracy

| | Fault Type | | | | | |
|---|---|---|---|---|---|---|
| | AG | | | | | |
| | Estimated | | BC | | ABG | |
| Variation of | (Estim.) | Error of | Estim. | Error of | Estim. | Error of |
| Pre-fault | FL | Estim. | FL | Estim. | FL | Estim. |
| Loading (%) | (p. u) | FL (%) | (p. u) | FL (%) | (p. u) | FL (%) |
| −50 | 0.5970 | 0.4934 | 0.5945 | 0.9088 | 0.5968 | 0.5294 |
| −20 | 0.5970 | 0.4951 | 0.5945 | 0.9139 | 0.5968 | 0.5289 |
| 20 | 0.5970 | 0.4967 | 0.5945 | 0.9117 | 0.5968 | 0.5286 |
| 50 | 0.5970 | 0.4975 | 0.5945 | 0.9126 | 0.5968 | 0.5285 |
| 100 | 0.5970 | 0.4982 | 0.5946 | 0.9077 | 0.5968 | 0.5285 |
| 200 | 0.5970 | 0.4978 | 0.5946 | 0.8990 | 0.5968 | 0.5288 |

Table 13 shows the influence of the compensation degree on the present adaptive PMU-based fault location method algorithm's accuracy for AG, BC and ABG faults assuming that these faults occur at a 0.6 p.u. distance from terminal A. The compensation degree is varied from 50% to 90%, for example. It is observed that the present algorithm is relatively highly accurate and virtually independent on the compensation degree with an average error of 0.519%, 0.886% and 0.532% for AG, BC and ABG faults, respectively. Plot 1900 of FIG. 19 depicts, for example, the effect of compensation degree on the present adaptive PMU-based fault location algorithm's fault location accuracy in embodiments of an adaptive PMU-based fault location method for SCLs.

TABLE 13
Influence of the Compensation Degree on the Present
Algorithm's Accuracy

| | Fault Type | | | | | |
|---|---|---|---|---|---|---|
| | AG | | | | | |
| | Estimated | | BC | | ABG | |
| Com- | (Estim.) | Error of | Estim. | Error of | Estim. | Error of |
| pensation | FL | Estim. | FL | Estim. | FL | Estim. |
| Degree (%) | (p. u) | FL (%) | (p. u) | FL (%) | (p. u) | FL (%) |
| 50 | 0.5967 | 0.5451 | 0.5950 | 0.8398 | 0.5969 | 0.5213 |
| 60 | 0.5968 | 0.5309 | 0.5947 | 0.8839 | 0.5969 | 0.5230 |
| 70 | 0.5969 | 0.5087 | 0.5947 | 0.8832 | 0.5967 | 0.5423 |
| 80 | 0.5969 | 0.5136 | 0.5945 | 0.9118 | 0.5967 | 0.5436 |
| 90 | 0.5970 | 0.4960 | 0.5945 | 0.9140 | 0.5968 | 0.5287 |

In the present adaptive PMU-based fault location method algorithm for SCLs, system impedance and line parameters are determined online and, thus, the effect of the surrounding environment and operation history on these parameters can be nullified. System impedance and line parameters determined online from PMU synchronized measurements can reflect the system's practical operating conditions prior to and after the fault occurrence, for example. In non-adaptive fault location algorithms, system impedance and line parameters typically are provided by the electric utility and assumed to be constant regardless of the environmental and system operating conditions. Such assumption, however, can be a source of error that can impact the fault location accuracy. In this regard, an investigation has been performed in relation to the effect of system impedance and line parameters uncertainty on fault location accuracy assuming that the system impedance and line parameters vary within ±25% from their practical values, for example.

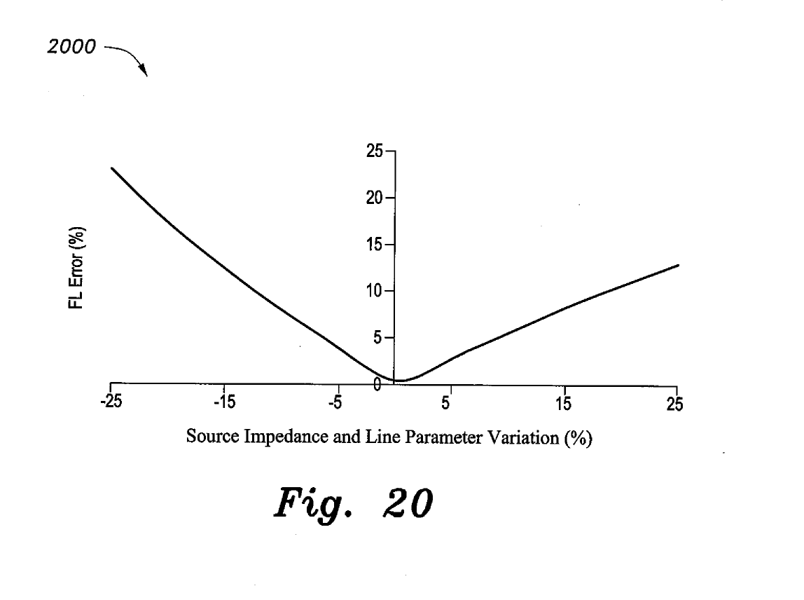

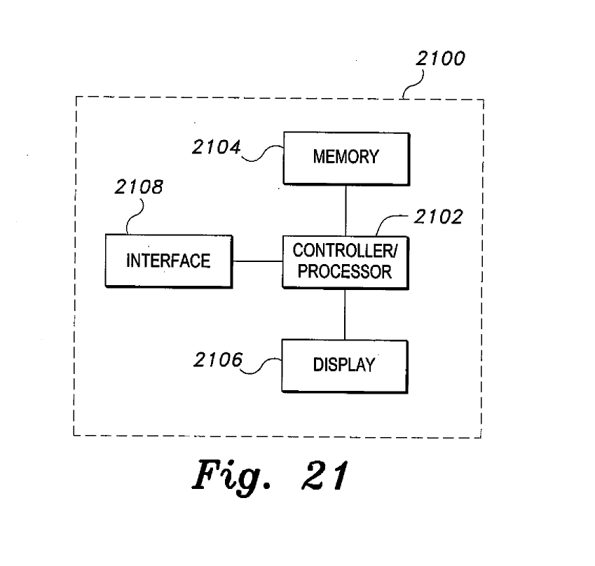

Table 14 shows the influence of the line parameters and the system impedance variation on the present algorithm's accuracy for AG, BC, CAG and ABC faults assuming that these faults occur at a 0.6 p.u. distance from terminal A. From the simulation results, it can be observed that the effect of the system impedance and the line parameters uncertainty on fault location can reach up to 23% if the parameters used in fault location vary by 25% of the practical parameters, for example. Plot 2000 of FIG. 20 depicts the effect of the system impedance and the line parameter variation on the present adaptive PMU-based fault location algorithm's accuracy in embodiments of an adaptive PMU-based fault location method for SCLs.

TABLE 14
Influence of Line Parameters and System Impedance
Variation on the Present Algorithm's Accuracy

Fault Type

| | AG | | | |
|---|---|---|---|---|
| | Error of | BC | CAG | ABC |
| | Estimated | Error of | Error of | Error of |
| Parameter | (Estim.) | Estim. | Estim. | Estim. |
| Variation (%) | FL (%) | FL (%) | FL (%) | FL (%) |
| −25 | 22.9009 | 23.4087 | 23.1150 | 22.8971 |
| −20 | 17.3029 | 17.7790 | 17.5037 | 17.2994 |
| −15 | 12.3635 | 12.8116 | 12.5525 | 12.3602 |
| −10 | 7.9730 | 8.3961 | 8.1514 | 7.9698 |
| −5 | 4.0446 | 4.4455 | 4.2136 | 4.0416 |
| 0 | 0.5090 | 0.8899 | 0.6696 | 0.5062 |
| 5 | 2.6899 | 2.3271 | 2.5369 | 2.6925 |
| 10 | 5.5979 | 5.2516 | 5.4519 | 5.6004 |
| 15 | 8.2531 | 7.9219 | 8.1134 | 8.2555 |
| 20 | 10.6870 | 10.3696 | 10.5531 | 10.6893 |
| 25 | 12.9261 | 12.6214 | 12.7976 | 12.9284 |

The present adaptive PMU-based fault location algorithm in embodiments of an adaptive PMU-based fault location method for SCLs can use synchronized phasor measurements obtained by PMUs, such as using a common time source for synchronization. Time synchronization can allow synchronized real-time measurements of multiple remote measurement points on the grid, for example. In this regard, embodiments of the present adaptive PMU-based fault location method for SCLs using the present adaptive PMU-based fault location algorithm typically do not require any data to be provided by the electric utility. Line parameters and Thevenin's equivalents of the system at both line terminals can be determined online using three independent sets of pre-fault PMU measurements. This can help overcome degradation of system impedance and line parameter uncertainty, for example.

The present adaptive PMU-based fault location algorithm also typically does not require the model of the series compensator (SC) or series compensation device assuming that the fault location function is available at SCL terminals. Further, fault-type selection is typically not required.

The present adaptive PMU-based fault location algorithm's accuracy is generally independent or substantially independent of a fault type, a fault location, a fault resistance, a fault inception angle, pre-fault loading and compensation degree, for example.

In comparison with a non-adaptive algorithm for SCLs, it has been observed that the effect of system impedance and parameters uncertainty on fault location can reach up to 23% if the parameters used in fault location vary by 25% of the practical parameters (see FIG. 20, plot 2000, for example).

It is to be understood that the present invention is not limited to the embodiments described above, but encompasses any and all embodiments within the scope of the following claims.

We claim:

1. An adaptive phasor measurement unit (PMU)-based fault location method for a series-compensated line (SCL), comprising the steps of:
acquiring three independent sets of pre-fault voltage and current (V_{A}, I_{A}) phasor measurements at a first terminal of a power system network;
acquiring three independent sets of pre-fault voltage and current (V_{B}, I_{B}) phasor measurements at a second terminal of said power system network, the three independent sets of PMU pre-fault phasor measurements at the first terminal (V_{A}, I_{A}) and the three independent sets of PMU pre-fault phasor measurements at the second terminal (V_{B}, I_{B}) having a common time reference;
determining the power system network's Thevenin Equivalent (TE) at the first terminal from the first terminal pre-fault phasor measurements;
determining the power system network's Thevenin Equivalent (TE) at the second terminal from the second terminal pre-fault phasor measurements;
determining line parameters and a voltage drop of a series compensator (SC) in the power system network using a least squares determination applied to each set of the pre-fault phasor measurements;
performing a symmetrical transformation of phasor quantities to obtain the corresponding positive, negative and zero sequence quantities;
determining fault distances of a first fault distance based on the symmetrical transformation using a fault loop on a first subroutine network (S_{A}) comprised of a line that includes the first terminal and the SC and of a second fault distance based on the symmetrical transformation using a fault loop on a second subroutine network (S_{B}) comprised of a line that includes the second terminal and the SC, for each subroutine network the total line length being the distance between the first terminal and the second terminal;
selecting as a valid subroutine network one from the group consisting of the first subroutine network (S_{A}) corresponding to the first determined fault distance and a second subroutine network (S_{B}) corresponding to the second determined fault distance; and
determining an actual fault location fault distance by a fault loop on the selected one of the first subroutine network (S_{A}) or the second subroutine network (S_{B}) as the valid subroutine network.

2. The adaptive PMU-based fault location method for a series-compensated line according to claim 1, wherein the line parameters determination step includes the determination of series resistance, series reactance and shunt admittance of the SCL.

3. The adaptive PMU-based fault location method for a series-compensated line according to claim 2, wherein the symmetrical transformation step further comprises determining a solution to the equation characterized by the relation:
$$[ \begin{matrix}{X}_{1} \\ {X}_{2} \\ {X}_{0}\end{matrix} ] = \frac{1}{3} [ \begin{matrix}1 & {e}^{j2 π / 3} & {e}^{j 4 π / 3} \\ 1 & {e}^{j 4 π / 3} & {e}^{j 2 π / 3} \\ 1 & 1 & 1\end{matrix} ] \cdot [ \begin{matrix}{X}_{a} \\ {X}_{b} \\ {X}_{c}\end{matrix} ] ,$$
where Xₐ, X_{b}, and X_{c} are the pre-fault phasors and X₁, X₂, and X₀ are the positive, negative and zero sequence phasors.

4. The adaptive PMU-based fault location method for a series-compensated line according to claim 3, wherein the determining fault distances step further comprises the step of determining the first fault distance for the first subroutine network (S_{A}), the first fault distance determination being characterized by the relation:
$${d}_{FA} = \frac{real ( {V}_{Ap} ) imag ( {I}_{FA} ) - imag ( {V}_{Ap} ) real ( {I}_{FA} )}{real ( {Z}_{1 LA} {I}_{Ap} ) imag ( {I}_{FA} ) - imag ( {Z}_{1 LA} {I}_{Ap} ) real ( {I}_{FA} )} ,$$
where V_{Ap} is the fault loop voltage for a fault on section A-X (between the first terminal and the SC), I_{Ap} is the fault loop current for a fault on section A-X, I_{FA} is the total fault current for a fault on section A-X, Z_{1LA} is the positive sequence impedance of the line section A-X, and d_{FA} is the relative distance FA (between the fault and the first terminal).

5. The adaptive PMU-based fault location method for a series-compensated line according to claim 4, wherein the determining fault distances step further comprises the step of calculating the second fault distance for the second subroutine network (S_{B}), the second fault distance determination being characterized by the relation:
$${d}_{FB} = \frac{real ( {V}_{Bp} ) imag ( {I}_{FB} ) - imag ( {V}_{Bp} ) real ( {I}_{FB} )}{real ( {Z}_{1 LB} {I}_{Bp} ) imag ( {I}_{FB} ) - imag ( {Z}_{1 LB} {I}_{Bp} ) real ( {I}_{FB} )} ,$$
where V_{Bp} is the fault loop voltage for a fault on section B-Y (between the second terminal and the SC), I_{Bp} is the fault loop current for a fault on section B-Y, I_{FB} is the total fault current for a fault on section B-Y, Z_{1LB} is the positive sequence impedance of the line section B-Y, and d_{FB} is the relative distance FB (between the fault and the second terminal).

6. The adaptive PMU-based fault location method for a series-compensated line according to claim 5, wherein the determining an actual fault location fault distance step is characterized by the following first relation when the first subroutine network (S_{A}) is the valid subroutine network:
d_{A}=d_{FA}·(l₁/l), and
characterized by the following second relation when the second subroutine network (S_{B}) is the valid subroutine network:
d_{B}=(l₁/l)+(1−d_{FB})·(l₂/l),
where d_{A} is the actual fault location fault distance where the first subroutine network (S_{A}) is the valid subroutine network, d_{FA} is the relative distance between the fault and the first terminal of the first subroutine network (S_{A}), d_{B} is the actual fault location fault distance where the second subroutine network (S_{B}) is the valid subroutine network, d_{FB} is the relative distance between the fault and the second terminal of the second subroutine network (S_{B}), l is the total line length, l₁ is a length of a line segment between the first terminal and the SC and l₂ is a length of a line segment between the second terminal and the SC.

7. The adaptive PMU-based fault location method for a series-compensated line according to claim 6, wherein the common time reference is achieved by synchronizing samples of the phasor measurements with reference to global positioning system (GPS) satellite transmissions received by at least one PMU disposed in the power system network.

8. The adaptive PMU-based fault location method for a series-compensated line according to claim 7, further comprising the step of:
using a Discrete Fourier Transform (DFT) to extract the voltage and current (V_{A}, I_{A}) phasors and the voltage and current (V_{B}, I_{B}) phasors, the DFT being characterized by the relation:
$$X = \frac{\sqrt{2}}{N} {\sum }_{k = 1}^{N} {x}_{k} {e}^{- j 2 π k / N} ,$$
where N is the total number of samples in one period, X is the phasor, and xₖ is the waveform samples.

9. The adaptive PMU-based fault location method for a series-compensated line according to claim 6, further comprising the step of:
using a Discrete Fourier Transform (DFT) to extract the voltage and current (V_{A}, I_{A}) phasors and the voltage and current (V_{B}, I_{B}) phasors, the DFT being characterized by the relation:
$$X = \frac{\sqrt{2}}{N} {\sum }_{k = 1}^{N} {x}_{k} {e}^{- j 2 π k / N} ,$$
where N is the total number of samples in one period, X is the phasor, and xₖ is the waveform samples.

10. The adaptive PMU-based fault location method for a series-compensated line according to claim 3, wherein the determining fault distances step further comprises the step of calculating the second fault distance for the second subroutine network (S_{B}), the second fault distance determination being characterized by the relation:
$${d}_{FB} = \frac{real ( {V}_{Bp} ) imag ( {I}_{FB} ) - imag ( {V}_{Bp} ) real ( {I}_{FB} )}{real ( {Z}_{1 LB} {I}_{Bp} ) imag ( {I}_{FB} ) - imag ( {Z}_{1 LB} {I}_{Bp} ) real ( {I}_{FB} )} ,$$
where V_{Bp} is the fault loop voltage for a fault on section B-Y (between the second terminal and the SC), I_{Bp} is the fault loop current for a fault on section B-Y, I_{FB} is the total fault current for a fault on section B-Y, Z_{1LB} is the positive sequence impedance of the line section B-Y, and d_{FB} is the relative distance FB (between the fault and the second terminal).

11. The adaptive PMU-based fault location method for a series-compensated line according to claim 3, further comprising the step of:
using a Discrete Fourier Transform (DFT) to extract the voltage and current (V_{A}, I_{A}) phasors and the voltage and current (V_{B}, I_{B}) phasors, the DFT being characterized by the relation:
$$X = \frac{\sqrt{2}}{N} {\sum }_{k = 1}^{N} {x}_{k} {e}^{- j 2 π k / N} ,$$
where N is the total number of samples in one period, X is the phasor, and xₖ is the waveform samples.

12. The adaptive PMU-based fault location method for a series-compensated line according to claim 3, wherein the determining an actual fault location fault distance step is characterized by the following first relation when the first subroutine network (S_{A}) is the valid subroutine network:
d_{A}⁼d_{FA}·(l₁/l), and
characterized by the following second relation when the second subroutine network (S_{B}) is the valid subroutine network:
d_{B}=(l₁/l)+(1−d_{FB})·(l₂/l),
where d_{A} is the actual fault location fault distance where the first subroutine network (S_{A}) is the valid subroutine network, d_{FA} is the relative distance between the fault and the first terminal of the first subroutine network (S_{A}), d_{B} is the actual fault location fault distance where the second subroutine network (S_{B}) is the valid subroutine network, d_{FB} is the relative distance between the fault and the second terminal of the second subroutine network (S_{B}), l is the total line length, l₁ is a length of a line segment between the first terminal and the SC and l₂ is a length of a line segment between the second terminal and the SC.

13. The adaptive PMU-based fault location method for a series-compensated line according to claim 12, wherein the common time reference is achieved by synchronizing samples of the phasor measurements with reference to global positioning system (GPS) satellite transmissions received by at least one PMU disposed in the power system network.

14. The adaptive PMU-based fault location method for a series-compensated line according to claim 2, wherein the determining an actual fault location fault distance step is characterized by the following first relation when the first subroutine network (S_{A}) is the valid subroutine network:
d_{A}=d_{FA}·(l₁/l), and
characterized by the following second relation when the second subroutine network (S_{B}) is the valid subroutine network:
d_{B}=(l₁/l)+(1−d_{FB})·(l₂/l),
where d_{A} is the actual fault location fault distance where the first subroutine network (S_{A}) is the valid subroutine network, d_{FA} is the relative distance between the fault and the first terminal of the first subroutine network (S_{A}), d_{B} is the actual fault location fault distance where the second subroutine network (S_{B}) is the valid subroutine network, d_{FB} is the relative distance between the fault and the second terminal of the second subroutine network (S_{B}), l is the total line length, l₁ is a length of a line segment between the first terminal and the SC and l₂ is a length of a line segment between the second terminal and the SC.

15. The adaptive PMU-based fault location method for a series-compensated line according to claim 14, wherein the common time reference is achieved by synchronizing samples of the phasor measurements with reference to global positioning system (GPS) satellite transmissions received by at least one PMU disposed in the power system network.

16. The adaptive PMU-based fault location method for a series-compensated line according to claim 2, wherein the common time reference is achieved by synchronizing samples of the phasor measurements with reference to global positioning system (GPS) satellite transmissions received by at least one PMU disposed in the power system network.

17. The adaptive PMU-based fault location method for a series-compensated line according to claim 1, further comprising the step of:
using a Discrete Fourier Transform (DFT) to extract the voltage and current (V_{A}, I_{A}) phasors and the voltage and current (V_{B}, I_{B}) phasors, the DFT being characterized by the relation:
$$X = \frac{\sqrt{2}}{N} {\sum }_{k = 1}^{N} {x}_{k} {e}^{- j 2 π k / N} ,$$
where N is the total number of samples in one period, X is the phasor, and xₖ is the waveform samples.

18. The adaptive PMU-based fault location method for a series-compensated line according to claim 1, wherein the symmetrical transformation step further comprises determining a solution to the equation characterized by the relation:
$$[ \begin{matrix}{X}_{1} \\ {X}_{2} \\ {X}_{0}\end{matrix} ] = \frac{1}{3} [ \begin{matrix}1 & {e}^{j2 π / 3} & {e}^{j 4 π / 3} \\ 1 & {e}^{j 4 π / 3} & {e}^{j 2 π / 3} \\ 1 & 1 & 1\end{matrix} ] \cdot [ \begin{matrix}{X}_{a} \\ {X}_{b} \\ {X}_{c}\end{matrix} ] ,$$
where Xₐ, X_{b}, and X_{c} are the pre-fault phasors and X₁, X₂, and X₀ are the positive, negative and zero sequence phasors.

19. The adaptive PMU-based fault location method for a series-compensated line according to claim 1, wherein the determining an actual fault location fault distance step is characterized by the following first relation when the first subroutine network (S_{A}) is the valid subroutine network:
d_{A}=d_{FA}·(l₁/l), and
characterized by the following second relation when the second subroutine network (S_{B}) is the valid subroutine network:
d_{B}=(l₁/l)+(1−d_{FB})·(l₂/l),
where d_{A} is the actual fault location fault distance where the first subroutine network (S_{A}) is the valid subroutine network, d_{FA} is the relative distance between the fault and the first terminal of the first subroutine network (S_{A}), d_{B} is the actual fault location fault distance where the second subroutine network (S_{B}) is the valid subroutine network, d_{FB} is the relative distance between the fault and the second terminal of the second subroutine network (S_{B}), l is the total line length, l₁ is a length of a line segment between the first terminal and the SC and l₂ is a length of a line segment between the second terminal and the SC.

20. The adaptive PMU-based fault location method for a series-compensated line according to claim 1, wherein the common time reference is achieved by synchronizing samples of the phasor measurements with reference to global positioning system (GPS) satellite transmissions received by at least one PMU disposed in the power system network.
